(19) United States
(12) Patent Application Publication
(10) Pub. No.: US 2010/0006891 A1
(43) Pub. Date: Jan. 14, 2010

(54) SEMICONDUCTOR THYRISTOR DEVICE

(75) Inventor: Fujiyuki Minesaki, Miyazaki (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/497,717

(22) Filed: Jul. 6, 2009

(30) Foreign Application Priority Data
Jul. 11, 2008 (JP) 2008-181391

(51) Int. Cl. H01L 29/74

(52) U.S. Cl. 257/173; 361/56; 257/E29.211

(57) ABSTRACT

A semiconductor thyristor device includes a semiconductor substrate, two transistors each of which is different junction type from the other and which are provided adjacent to each other in the semiconductor substrate to constitute one thyristor element, a first wiring layer that is formed on the semiconductor substrate and provides a ground potential to one of the transistors, and a second wiring layer that is formed on the semiconductor substrate and provides a power source potential to the other of the transistors. The first wiring layer covers a region in the semiconductor substrate in which the two transistors adjoin each other. This avoids a leakage current that might be generated due to any potential of a wiring layer for another circuit in a chip layout.

### BACKGROUND OF THE INVENTION

1. Field of the Invention

The present invention relates to a semiconductor thyristor device, and more particularly to a semiconductor thyristor device which can function as a power protection circuit for any functional circuit.

2. Description of the Related Art

FIG. 1 illustrates a PMOS trigger Silicon Controlled Rectifier (SCR) circuit as a conventional semiconductor thyristor that functions as a power protection circuit. The operating principle of this circuit is as follows. In the case where the potential of a VDD line is abnormally raised due to surge, a PMOS transistor Q2 connected to the VDD line through a resistor R1 breaks down, causing a trigger current to flow. This reduces the potential of an N-type well of an NPN transistor Q0 to turn on the semiconductor thyristor device, thereby causing an ESD surge current to flow through a PNP transistor Q1. This enables protection of a functional circuit connected between a power source potential VDD and a ground potential GND.

FIGS. 2A and 2B illustrate cross-sectional and planar structures of the semiconductor thyristor device shown in FIG. 1. As shown in FIG. 2A, the NPN transistor Q0 is formed through a combination of N-P-N junctions of an N-type high-concentration region 14, a P-type well 11, and an N-type high-concentration region 16 in series, and the PNP transistor Q1 is formed through a combination of P-N-P junctions of a P-type high-concentration region 15, an N-type well 12, and the P-type well 11 in series. The semiconductor thyristor device shown in FIG. 1 is formed through connection of these two junction transistors. Generally, the potential of the N-type well 12 is set to the power source potential VDD and the substrate potential is set to the ground potential GND.

FIG. 2B illustrates a shape of the semiconductor thyristor device, having the cross-section shown in FIG. 2A, when viewed from the top. As shown in FIG. 2B, the P-type high-concentration region 13 and the N-type high-concentration region 14 in the P-type well 11 are covered with a metal wiring layer 21, and the P-type high-concentration region 15 and the N-type high-concentration region 16 in the N-type well 12 are covered with a metal wiring layer 22. As a result, a surface portion of the P-type well 11 located between the metal wiring layer 21 and the N-type well 12 is exposed.

In the cross-sectional structure shown in FIG. 2A, a metal wiring layer as a power source line or a signal line may be provided at an upper position in a substrate region A. In this case, a parasitic NMOS transistor is created, wherein the metal wiring layer 23 serves as a gate region formed through an insulating layer 19, and the N-type high-concentration region 14 and the N-type well 12 serve as source and drain regions respectively. Due to a potential (for example, VDD2) applied to the metal wiring layer 23, the parasitic NMOS transistor is turned on to generate a leakage current in the substrate, which may cause malfunction of the thyristor element included in the semiconductor thyristor device.

Japanese Patent Application Publication No. 55-123157 describes a method for preventing leakage current in an impurity-diffused layer resister. This publication suggests a structure in which a metal wiring layer having a positive potential is disposed on an impurity-diffused layer resister formed on a substrate with an oxide layer being formed therebetween. In this structure, the metal wiring layer prevents a reversed layer from being created on the surface of the impurity-diffused layer resister due to influence of negative ions inside the oxide layer on the impurity-diffused layer resister, thereby preventing reduction of resistance of the impurity-diffused layer resister.

However, the technology described in Japanese Patent Application Publication No. 55-123157 assumes a different configuration and a different leakage current generation mechanism from those of the conventional semiconductor thyristor device described above, and still cannot avoid generation of a leakage current due to a parasitic NMOS transistor in the conventional semiconductor thyristor device.

### SUMMARY OF THE INVENTION

Therefore, the present invention has been made in view of the above problems, and it is an object of the present invention to provide a semiconductor thyristor device which can avoid a leakage current that might be generated due to any potential of a wiring layer for another circuit in a chip layout.

In accordance with the present invention, the above and other objects can be accomplished by the provision of a semiconductor thyristor device includes a semiconductor substrate, two transistors each of which has different junction type from the other and which are provided adjacent to each other in the semiconductor substrate to constitute one thyristor element, a first wiring layer that is formed on the semiconductor substrate and provides a ground potential to one of the transistors, and a second wiring layer that is formed on the semiconductor substrate and provides a power source potential to the other of the transistors, wherein the first wiring layer covers a region in the semiconductor substrate in which the two transistors adjoin each other.

The semiconductor thyristor device according to the present invention avoids a leakage current that might be generated due to any potential of a wiring layer for another circuit in a chip layout.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram illustrating a conventional semiconductor thyristor device;

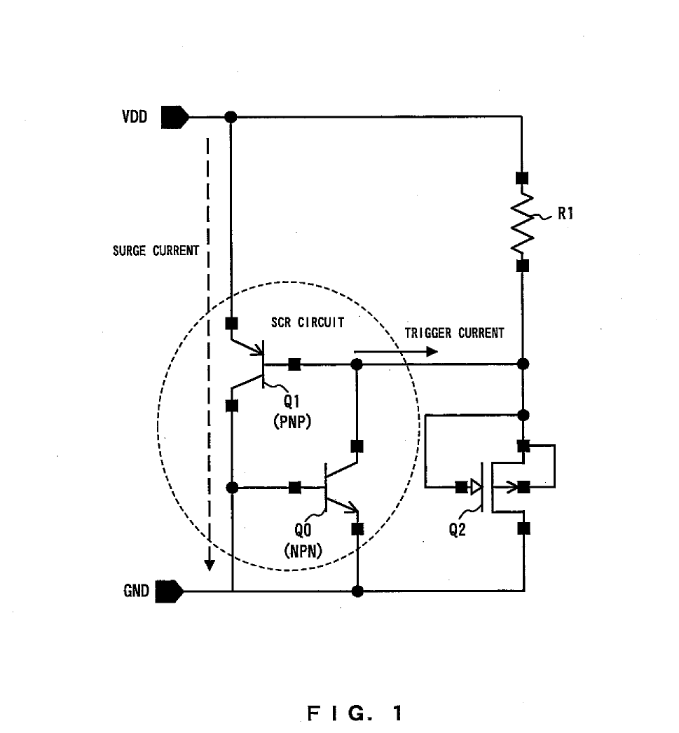

FIG. 2A is a cross-sectional view of the semiconductor thyristor device shown in FIG. 1;

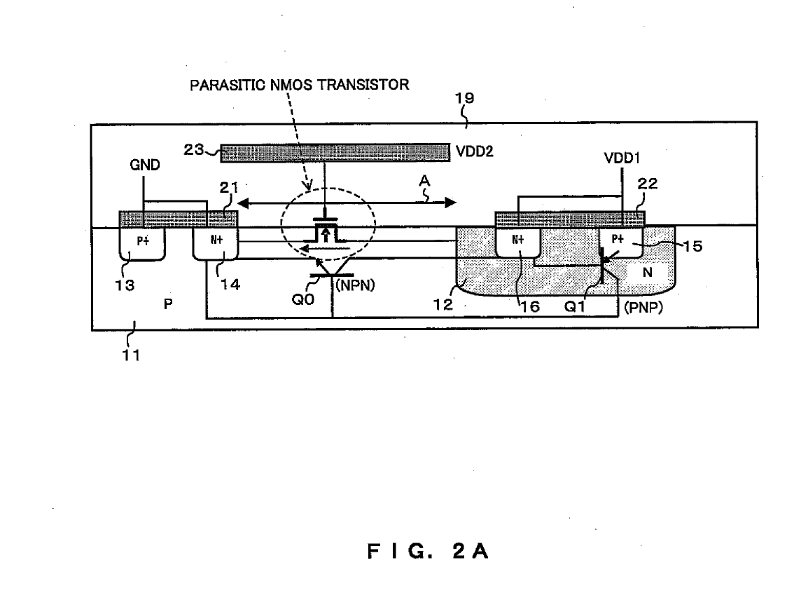

FIG. 2B is a plan view of the semiconductor thyristor device shown in FIG. 1;

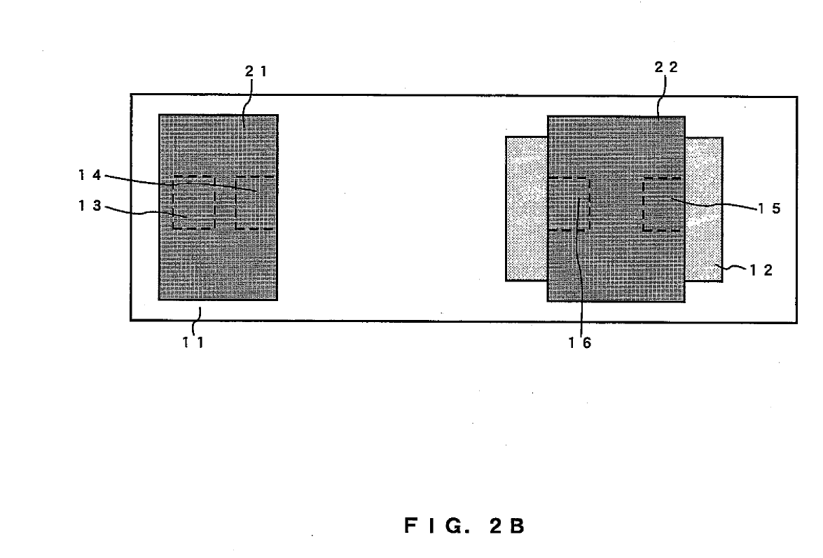

FIG. 3 is a block diagram illustrating a configuration of a semiconductor thyristor device according to an embodiment of the present invention;

FIG. 4 is a plan view of the semiconductor thyristor device shown in FIG. 3 when viewed from the top;

FIG. 5A is a block diagram illustrating an example of application of the semiconductor thyristor device according to the present invention;

FIG. 5B is an enlarged block diagram of a power protection circuit shown in FIG. 5A; and

FIG. 5C is an enlarged block diagram of a semiconductor thyristor device shown in FIG. 5B.

### DETAILED DESCRIPTION OF THE INVENTION

Embodiments of the present invention will now be described in detail with reference to the accompanying drawings.

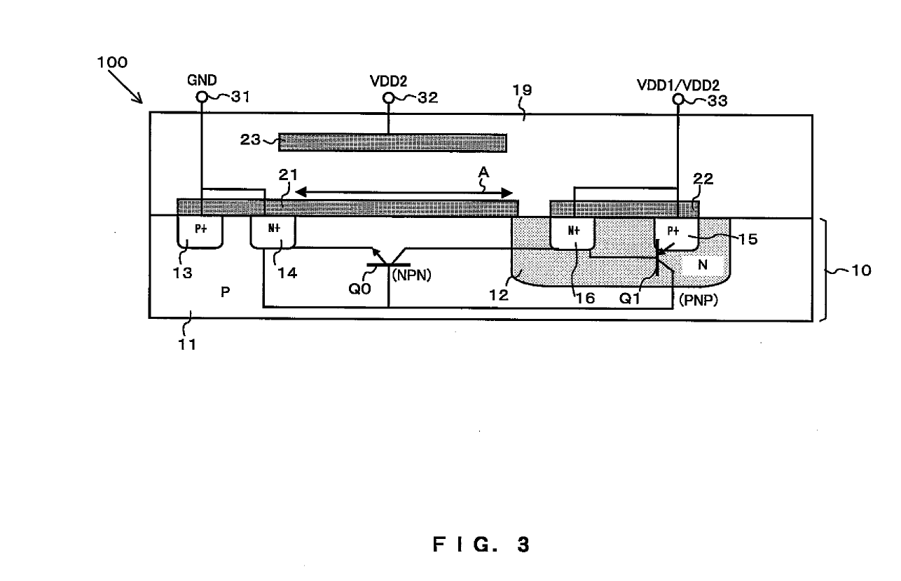

FIG. 3 illustrates a cross-section of a semiconductor thyristor device according to an embodiment of the present invention. In this embodiment, the semiconductor thyristor device 100 is formed on at least a part of a substrate 10 made of a substance such as silicon. A P-type well 11 is formed in the substrate 10 and an N-type well 12 is formed in the P-type well 11. A functional circuit (not shown) may be provided on the substrate 10. In this case, the semiconductor thyristor device 100 is designed to operate as a power protection circuit for the functional circuit.

A P-type high-concentration region 13 and an N-type high-concentration region 14 are formed in the P-type well 11. The tops of the P-type high-concentration region 13 and the N-type high-concentration region 14 are exposed at a top surface of the substrate 10 and are electrically connected to a metal wiring layer 21 provided on the exposed surface. The metal wiring layer 21 is made of a wiring substance such as copper or aluminum and is connected to a power source terminal 31 such that a ground potential GND is provided to the metal wiring layer 21.

A P-type high-concentration region 15 and an N-type high-concentration region 16 are formed in the N-type well 12. The tops of the P-type high-concentration region 15 and the N-type high-concentration region 16 are exposed at the top surface of the substrate 10 and are electrically connected to a metal wiring layer 22 provided on the exposed surface. The metal wiring layer 22 is made of a wiring substance such as copper or aluminum and is connected to a power source terminal 33 such that a power source potential VDD1 or VDD2 is provided to the metal wiring layer 22.

In the configuration of the substrate described above, an NP junction is formed between the N-type high-concentration region 14 and the P-type well 11, a PN junction is formed between the P-type well 11 and the N-type high-concentration region 16, and an NPN transistor Q0 is formed through these junctions. In addition, a PN junction is formed between the P-type high-concentration region 15 and the N-type well 12, an NP junction is formed between the N-type well 12 and the P-type well 11, and a PNP transistor Q1 is formed through these junctions.

As shown, the N-type high-concentration region 14 which corresponds to an emitter region of the NPN transistor Q0 is connected to the ground potential GND through the metal wiring layer 21. In addition, the P-type well 11 which corresponds to a base region of the NPN transistor Q0 is connected to the N-type high-concentration region 14 which corresponds to the emitter region. The N-type high-concentration region 16 and the N-type well 12 which correspond to a collector region of the NPN transistor Q0 are connected to the power source potential VDD through the metal wiring layer 22.

On the other hand, the P-type high-concentration region 15 which corresponds to an emitter region of the PNP transistor Q1 is connected to the power source potential VDD through the metal wiring layer 22. The N-type high-concentration region 16 and N-type well 12 which corresponds to a base region of the PNP transistor Q1 are connected to the power source potential VDD through the metal wiring layer 22. In addition, the P-type well 11 which corresponds to the collector region of the PNP transistor Q1 is commonly the base region of the NPN transistor Q0 so that both of the regions are connected.

In the configuration described above, the NPN transistor Q0 and the PNP transistor Q1 are formed in the substrate 10 such that they adjoin each other in an appropriate connection relation to form a thyristor element in the substrate 10. This thyristor element is combined with a trigger PMOS transistor (not shown) to implement the semiconductor thyristor device 100.

In this embodiment, the semiconductor thyristor device is also covered with an appropriate insulating layer 19 such as a silicon oxide layer. A metal wiring layer 23 is formed in the insulating layer 19. The metal wiring layer 23 is made of a wiring substance such as copper or aluminum. For example, the metal wiring layer 23 may be a power source line or a signal line for a functional circuit (not shown). In the example of FIG. 3, the metal wiring layer 23 is connected to a power source terminal 32 such that a power source potential VDD2 is provided to the metal wiring layer 23. The metal wiring layer 21 in the semiconductor thyristor device 100 extends along a region A such that the metal wiring layer 21 covers the region A, which has a size corresponding to the size of the metal wiring layer 23. Accordingly, the metal wiring layer 21 shields an electric field that is generated due to the potential of the metal wiring layer 23.

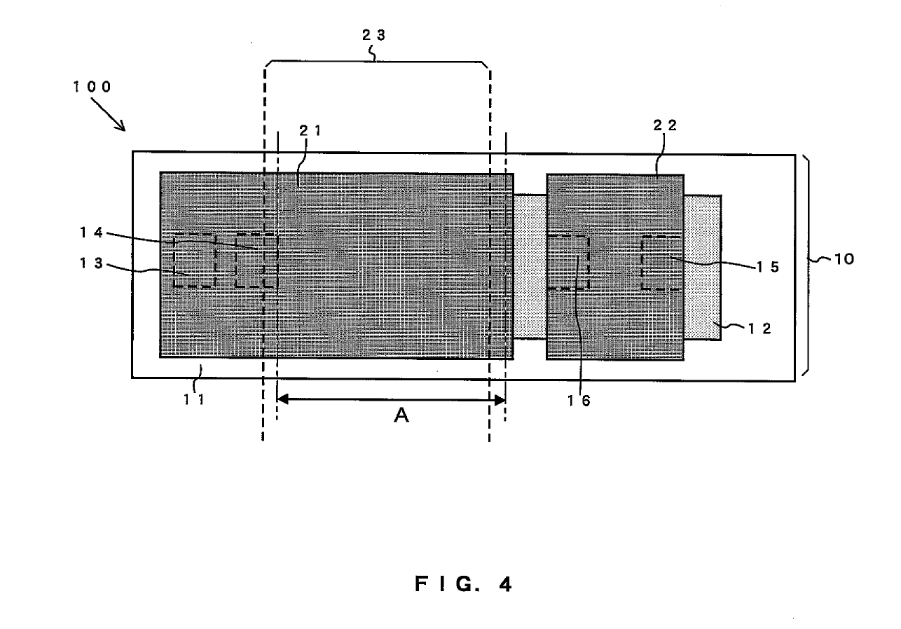

FIG. 4 illustrates a shape of the semiconductor thyristor device shown in FIG. 3 when viewed from the top. The semiconductor thyristor device 100 has a structure corresponding to that shown in FIG. 3 and includes a P-type well 11 and an N-type well 12 and the P-type well 11 includes a P-type high-concentration region 13 and an N-type high-concentration region 14. The N-type well 12 includes a P-type high-concentration region 15 and an N-type high-concentration region 16. The P-type high-concentration region 15 and the N-type high-concentration region 16 are covered with a metal wiring layer 22. A metal wiring layer 21 covers the P-type high-concentration region 13 and the N-type high-concentration region 14 and also covers the P-type well 11 such that an end portion of the metal wiring layer 21 extends to near the N-type well 12 within a range in which the metal wiring layer 21 is not electrically connected to the metal wiring layer 22. While the metal wiring layer 21 covers at least a part of the source region of the NPN transistor Q0 shown in FIG. 3, there is a need to adjust the width of the metal wiring layer 21 (in the vertical direction in FIG. 4) to a width at which the metal wiring layer 21 prevents a leakage current from being generated by the influence of the potential of the metal wiring layer 23 (shown by a dashed line in FIG. 4). Particularly, it is most preferable that the metal wiring layer 21 extend such that an end portion of the metal wiring layer 21 reaches the N-type well 12 (i.e., the base region of the PNP transistor Q1) within a range in which the metal wiring layer 21 is not electrically connected to the metal wiring layer 22. Of course, as long as the metal wiring layer 21 is not electrically connected to the metal wiring layer 22, the metal wiring layer 21 may be wide such that it not only covers the base region of the NPN transistor Q0 but also covers a region in which the NPN transistor Q0 and the PNP transistor Q1 adjoin each other.

In this embodiment, the metal wiring layer 21 covers at least the base region of the NPN transistor Q0. This prevents the generation of leakage current due to a parasitic MOS transistor between the NPN transistor Q0 and the PNP transistor Q1 which operate together to form a thyristor element. Even though a wiring other than the ground line, such as a wiring through which a power source potential or a functional signal is provided, is provided above the P-type well, the wiring does not cause malfunction of the thyristor element, thereby improving the degree of freedom of wirings. Especially, if an end portion of the metal wiring layer 21 reaches the N-type well 12 (i.e., the base region of the PNP transistor Q1) while the metal wiring layer 21 covers the base region of the NPN transistor Q0, it is possible to more effectively prevent the generation of leakage current due to the parasitic MOS transistor.

Although one of the two transistors, which are the components of the semiconductor thyristor device 100 according to the present inventions is the NPN transistor Q0 while the other is the PNP transistor Q1 in the above embodiment, the semiconductor thyristor device 100 may also have a reversed transistor structure such that one of the two transistors is a PNP transistor Q0 while the other is an NPN transistor Q1 and a P-type well and an N-type well may be previously formed appropriately according to this reversed structure in a semiconductor substrate.

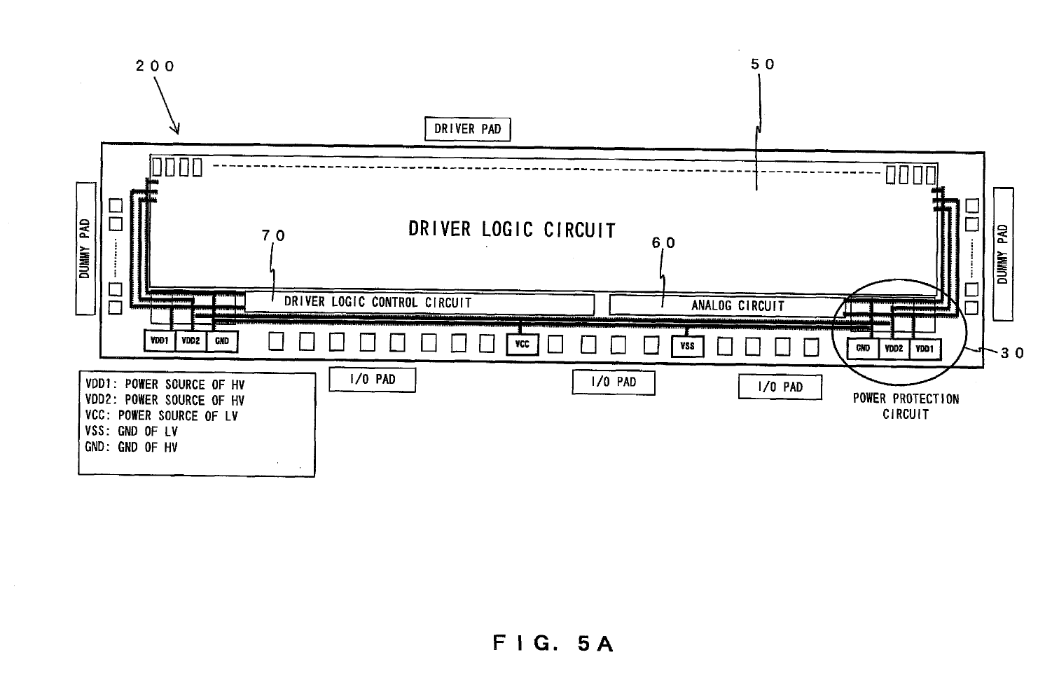

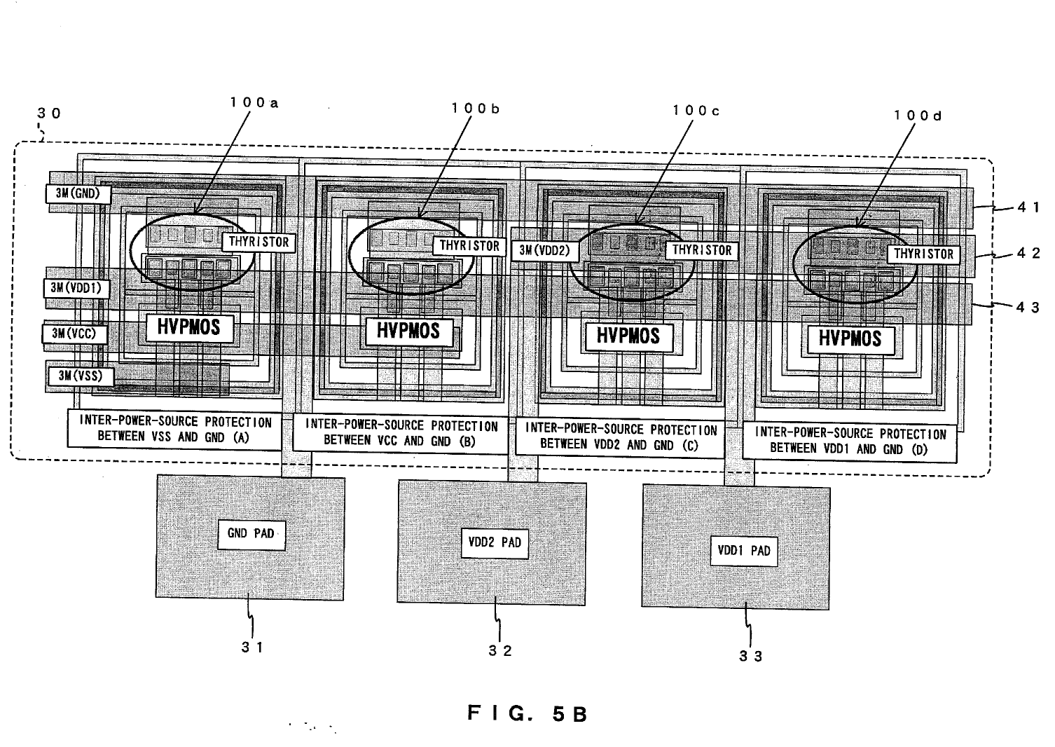

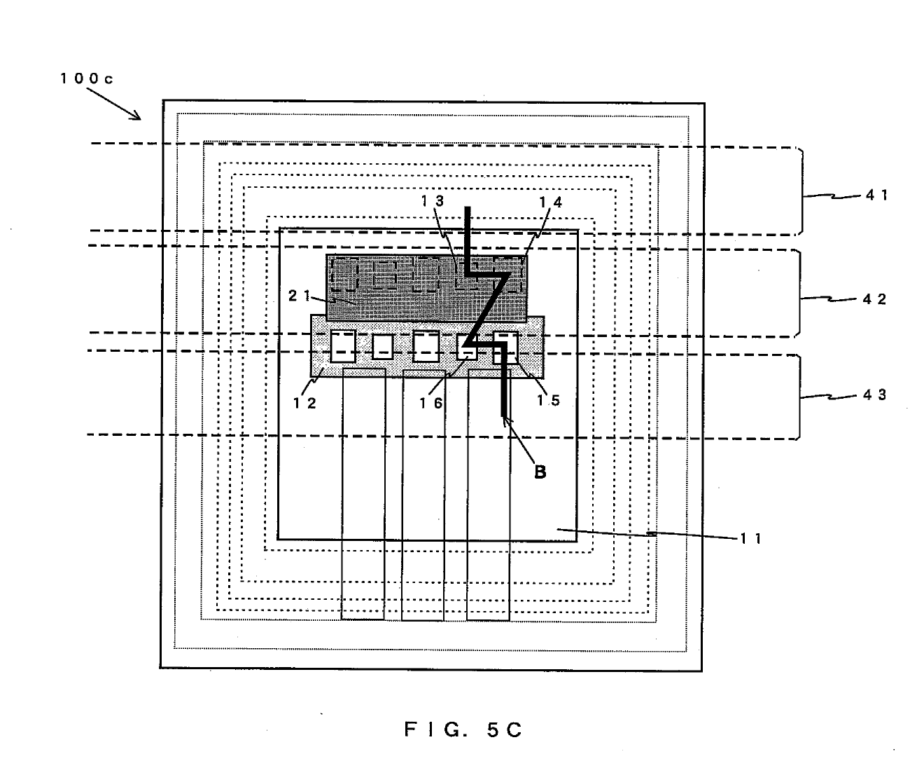

FIGS. 5A to 5C illustrate examples of application of the semiconductor thyristor device according to the present invention. As shown in FIG. 5A, an LCD driver chip 200 includes a semiconductor thyristor device according to the present invention. For example, the LCD driver chip 200 is a semiconductor chip that is manufactured as an LCD driver for an LCD panel such as an STN-type LCD panel. For example, the LCD driver chip 200 includes a driver logic circuit 50 as a functional circuit, a driver logic controller circuit 70 that controls the driver logic circuit 50, an analog circuit 60 that generates and provides a reference voltage to the driver logic circuit 50, and a power protection circuit 30 that absorbs an ESD voltage (i.e., a surge voltage). The LCD driver chip 200 is provided as a Tape Carrier Package (TCP)-type chip package.

FIG. 5B is an enlarged view of the power protection circuit 30 shown in FIG. 5A. In order to absorb an ESD voltage which might be generated between the power source line and the ground line, the power protection circuit 30 includes four semiconductor thyristor devices 100a to 100d, each of which is implemented as the semiconductor thyristor device according to the present invention shown in FIGS. 3 to 4. The power protection circuit 30 includes a plurality of power source pads 31 to 33 for receiving potentials from the outside of the power protection circuit 30. A ground potential GND is provided to the power source pad 31, a power source potential VDD2 is provided to the power source pad 32, and a power source potential VDD1 is provided to the power source pad 33. These plurality of potentials are provided to the power protection circuit 30 through metal wiring layers 41 to 43, respectively, and are also provided to a functional circuit such as the driver logic circuit 50 (shown in FIG. 5A). The power protection circuit 30 is most preferably provided adjacent to the power source pads 31 to 33 as shown in FIG. 5B, and it is possible to improve ESD voltage resistance by reducing the resistances of wirings between the power source pads 31 to 33 and the power protection circuit 30.

FIG. 5C is an enlarged view of the semiconductor thyristor device 100c shown in FIG. 5B. The semiconductor thyristor device 100c includes a P-type well 11 and an N-type well 12. A P-type high-concentration region 13 and an N-type high-concentration region 14 are formed in the P-type well 11. A P-type high-concentration region 15 and an N-type high-concentration region 16 are formed in the N-type well 12. There is a risk of a parasitic MOS transistor being created in a region in which the P-type high-concentration region 13 and the N-type high-concentration region 14 adjoin the P-type high-concentration region 15 and the N-type high-concentration region 16. Especially, the metal wiring layer 42 crosses this region, among the three metal wiring layers 41 to 43 which are laid out above the semiconductor thyristor device 100c.

The metal wiring layer 21 for providing the ground potential GND is wide such that it not only covers the P-type high-concentration region 13 and the N-type high-concentration region 14 but also covers up to a portion near the N-type well 12, thereby shielding the influence of the potential of the metal wiring layer 42.

In addition, the arrangement of the series of regions including the P-type high-concentration region 13, the N-type high-concentration region 14, the P-type high-concentration region 15, and the N-type high-concentration region 16 is not limited to a linear form, and the regions may also be arranged in a form shown by a bent line B in FIG. 5C. In this case, the metal wiring layer 21 also covers a wide area including a region adjacent to the N-type well 12, thereby further increasing the shielding effect. The bent line B corresponds to the cross-section shown in FIG. 3.

As is understood from the LCD driver chip shown in FIGS. 5A to 5C, in the case where a variety of functional circuits and a power protection circuit are provided on a chip that is spatially restricted, there is a need to provide a number of power source or signal lines on a substrate at upper positions while wirings other than the ground line such as power source or signal lines cannot be disposed above the power protection circuit. If these wirings are not allowed to be disposed above the power protection circuit, the degree of freedom of wirings is significantly reduced. In the case of 5B, the metal wiring layer 42 for providing the power source potential VDD2 is laid out above the substrate of the power protection circuit 30 and crosses over the semiconductor thyristor device 100c and the semiconductor thyristor device 100d included in the power protection circuit 30.

In this layout, the parasitic MOS transistor, which causes a leakage current, is also shielded by the ground potential using the power protection circuit including a semiconductor thyristor device according to the present invention, thereby preventing the generation of the leakage current. Accordingly, it is possible to more freely lay out wirings on a substrate and thus to more easily manufacture a product integrated with high precision.

Especially, since the metal wiring layer 21 not only covers the P-type high-concentration region 13 and the N-type high-concentration region 14 but also covers a portion of the P-type well 11 between the N-type well 12 and the P-type and N-type high-concentration regions 13 and 14 while an end portion of the metal wiring layer 21 reaches the N-type well 12, it is possible to very effectively prevent the generation of leakage current.

The semiconductor thyristor device according to the present invention can be used not only in a power protection circuit for an LCD driver but also in a circuit which includes a thyristor element formed on a substrate and which may further include a variety of layouts such as a layout including power source lines. Although the upper wiring layer is a wiring layer for providing a power source potential in the above example application (shown in FIGS. 5A and 5B), it may also be a wiring layer for transferring a functional signal to the driver logic circuit 50 and an external input/output pad.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

This application is based on Japanese Patent Application No. 2008-181391 which is hereby incorporated by reference.

What is claimed is:

1. A semiconductor thyristor device comprising:
a semiconductor substrate;
two transistors each of which has different junction type from the other and which are provided adjacent to each other in the semiconductor substrate to constitute one thyristor element;
a first wiring layer that is formed on the semiconductor substrate and provides a ground potential to one of the transistors; and
a second wiring layer that is formed on the semiconductor substrate and provides a power source potential to the other of the transistors,
wherein the first wiring layer covers a region in the semiconductor substrate in which the two transistors adjoin each other.

2. The semiconductor thyristor device according to claim 1, wherein the first wiring layer covers at least a base region of the one transistor in the region in which the two transistors adjoin each other.

3. The semiconductor thyristor device according to claim 2, wherein an end portion of the first wiring layer reaches a base region of the other transistor.

4. The semiconductor thyristor device according to claim 1, further comprising an insulating layer that is provided covering the first and second wiring layers and electrically insulates the first and second wiring layers from an upper wiring layer.

5. The semiconductor thyristor device according to claim 4, wherein the upper wiring layer is a wiring layer for providing a potential other than the ground potential.

6. The semiconductor thyristor device according to claim 4, wherein the upper wiring layer is a wiring layer for connecting a signal pad and a functional circuit provided on the semiconductor substrate.

7. The semiconductor thyristor device according to claim 1, wherein the thyristor element constitutes a power protection circuit that absorbs a surge voltage that may be generated between the ground potential and the power source potential.

8. The semiconductor thyristor device according to claim 7, wherein the power protection circuit is disposed adjacent to a power source pad that receives the power source potential from the outside of the power protection circuit.
